(19) United States
(12) Patent Application Publication
(10) Pub. No.: US 2025/0007289 A1
(43) Pub. Date: Jan. 2, 2025

(54) SIMULATION TEST SYSTEM AND PERFORMANCE DETECTION METHOD FOR HYBRID POWER CONVERSION SYSTEM

(71) Applicant: INNER MONGOLIA POWER (GROUP) CO., LTD INNER MONGOLIA POWER RESEARCH INSTITUTE, Huhhot (CN)

(72) Inventors: Zaixin YANG, Huhhot (CN); Minfu A, Huhhot (CN); Baiqing YIN, Huhhot (CN); Hongbin HU, Huhhot (CN); Xusheng JIAN, Huhhot (CN); Yin ZHAI, Huhhot (CN); Xinzhe GAO, Huhhot (CN)

(73) Assignee: INNER MONGOLIA POWER (GROUP) CO., LTD INNER MONGOLIA POWER RESEARCH INSTITUTE, Huhhot (CN)

(21) Appl. No.: 18/689,442

(22) PCT Filed: Nov. 29, 2023
(86) PCT No.: PCT/CN2023/135134

§ 371 Date: Mar. 6, 2024

(30) Foreign Application Priority Data
Nov. 29, 2022 (CN) 202211515596.X

(51) Int. Cl. H02J 3/32; G05B 17/00; H02J 3/38

(52) U.S. Cl. CPC H02J 3/32; G05B 17/00; H02J 3/381; H02J 2203/20; H02J 2300/24; H02J 2300/28

(57) ABSTRACT

A simulation test system and a performance detection method for a hybrid power conversion system are provided. The system includes a simulation workstation, a real-time digital simulator, an I/O interface device, and a to-be-tested hybrid energy storage controller. The simulation workstation sends an operation control instruction to the real-time digital simulator which simulates an operation working condition or an abnormal working condition of various faults of the simulation workstation in real time; the I/O interface device implements data interaction between the real-time digital simulator and the to-be-tested hybrid energy storage controller; the to-be-tested hybrid energy storage controller generates a switch tripping and closing instruction and a trigger pulse signal; and the real-time digital simulator sends the switch tripping and closing instruction and the trigger pulse signal to the simulation workstation, so that the simulation workstation performs simulation based on the switch tripping and closing instruction and the trigger pulse signal.

### CROSS-REFERENCE TO RELATED APPLICATION

The present disclosure claims priority to Chinese Patent Application No. 202211515596.X, filed with the China National Intellectual Property Administration on Nov. 29, 2022 and entitled “SIMULATION TEST SYSTEM AND PERFORMANCE DETECTION METHOD FOR HYBRID POWER CONVERSION SYSTEM”, the content of which is incorporated herein by reference in its entirety.

### TECHNICAL FIELD

The present disclosure relates to the technical field of simulation tests, and in particular, to a simulation test system and a performance detection method for a hybrid power conversion system.

### BACKGROUND

With the large-scale integration of new energy sources represented by wind energy and solar energy into a power grid and the application of a large number of power electronic devices in a power system, the power supply structure, power grid form, load characteristics, operation mode and the like will all undergo profound changes, which increases the difficulty of peak load and frequency regulation of the system. An energy storage power station is regarded as a power grid side technical solution to improve the frequency stability of the system, has unique advantages in peak cut and rapid frequency regulation, and can provide power response and inertia support for the power system.

A power conversion system (PCS) is a core component of an electric energy storage system. However, a topological structure and a control strategy of the power conversion system have a great impact on grid-connected performance, and a conventional solution based on a two-level converter is difficult to adapt to a high-proportion new energy power system containing large-scale energy storage. Therefore, high-capacity and hybrid type have become two major development trends and technical directions of energy storage system configuration.

In an aspect of high-capacity power conversion system topology, a distributed configuration solution based on a multi-level (three-level or more) converter is a preferable solution for achieving medium-voltage high-capacity alternating current-direct current electric energy conversion. Since it is difficult to further improve the performance of a silicon-based power device IGBT commonly used in recent years, a heterogeneous power device, hybrid multi-level converter, which is applied by mixing a silicon carbide MOSFET and a silicon device is beneficial to saving cost, reducing loss and improving power density and overall efficiency. However, related research is still in its infancy.

Meanwhile, the high-capacity hybrid energy storage technology lacks construction and operation experience at home, and especially lacks technical verification means. At present, for model verification of power electronic devices, relatively mature software such as PLECS and MATLAB/Simulink is mainly used for simulation modeling, which can analyze the electrical characteristics of components, converter topology, modulation strategies and the like from the device level. However, a simulation model and a dynamic simulation test platform for detecting a large-capacity power conversion system integrated with a hybrid energy storage unit are not available for reference, and there is a lack of an effective means and method for determining whether a control strategy is suitable for a large power grid after heterogeneous power device integration.

### SUMMARY

In view of this, the present disclosure aims to provide a simulation test system and a performance detection method for a hybrid power conversion system, which provide a semi-physical closed-loop simulation system and a detection method with strong adaptability and good compatibility for grid-connected performance of the hybrid power conversion system, and verify the electrical performance and the control strategy of the hybrid power conversion system, so as to be suitable for safe and stable operation of a large-scale energy storage power station.

According to a first aspect, embodiments of the present disclosure provide a simulation test system for a hybrid power conversion system. The simulation test system for a hybrid power conversion system includes a simulation workstation, a real-time digital simulator, an I/O interface device, and a to-be-tested hybrid energy storage controller, where the simulation workstation is in communication with the real-time digital simulator, the real-time digital simulator is connected to the I/O interface device through an optical fiber, and the I/O interface device is in communication with the to-be-tested hybrid energy storage controller;
the simulation workstation is configured to generate an operation control instruction in response to a user operation and send the operation control instruction to the real-time digital simulator;
the real-time digital simulator is configured to simulate an operation working condition or an abnormal working condition of various faults of the simulation workstation in real time, complete operation processing according to the operation control instruction, generate corresponding data volume and send the data volume to the I/O interface device through an optical fiber, where the data volume includes grid side voltage and current, direct current side voltage and current, grid side switch state and direct current side switch state;
the I/O interface device is configured to implement data interaction between the real-time digital simulator and the to-be-tested hybrid energy storage controller and send the data volume generated by the real-time digital simulator to the to-be-tested hybrid energy storage controller;
the to-be-tested hybrid energy storage controller is configured to generate a switch tripping and closing instruction and a trigger pulse signal based on the received data volume, and send the switch tripping and closing instruction and the trigger pulse signal to the real-time digital simulator through the I/O interface device, where the switch tripping and closing instruction includes a grid side switch tripping and closing instruction and a direct current side switch tripping and closing instruction; and the real-time digital simulator is configured to send the switch tripping and closing instruction and the trigger pulse signal to the simulation workstation, so that the simulation workstation performs simulation based on the switch tripping and closing instruction and the trigger pulse signal.

Further, the simulation workstation includes an energy storage substation and external power grid module, a hybrid power conversion system test model, an energy storage battery pack model and a fault simulation module;
the energy storage substation and external power grid module is configured to simulate working states of an energy storage substation and an external equivalent power grid;
the hybrid power conversion system test model is configured to simulate the hybrid power conversion system;
the energy storage battery pack model is configured to form a battery cluster in a series-parallel connection mode and access the battery cluster to a direct current side in the energy storage substation and external power grid module; and
the fault simulation module is configured to simulate a fault state to verify a control protection function of a hybrid power conversion system in the hybrid power conversion system test model.

Further, the energy storage substation and external power grid module includes a 220 kV side primary system model of the energy storage substation, an external power grid model and a 10 kV energy storage side primary system model;
the 220 kV side primary system model further includes a 220 kV bus, a 110 kV bus, a 10 kV bus, a circuit breaker, a transformer and in-station reactive compensation equipment;
the external power grid model further includes two 220 kV transmission lines, a wind power plant, a photovoltaic power station and a fossil-fuel power station;
the 10 kV energy storage side primary system model further includes a grid-connected switch, a step-up transformer switch, a load switch and a comprehensive load; and
the hybrid power conversion system test model includes at least one conventional power conversion system and a hybrid power conversion system model, where the hybrid power conversion system is simulated by using a hybrid three-level ANPC topology.

Further, the to-be-tested hybrid energy storage controller includes a sampling unit, a switch quantity control unit and a drive circuit;
the sampling unit is configured to collect the grid side voltage and current and the direct current side voltage and current which are sent by the I/O interface device;
the switch quantity control unit is configured to generate the grid side switch tripping and closing instruction and the direct current side switch tripping and closing instruction based on the grid side switch state and the direct current side switch state; and
the drive circuit is configured to generate the trigger pulse signal.

Further, the simulation test system for a hybrid power conversion system further includes a digital recorder, and the real-time digital simulator and the to-be-tested hybrid energy storage controller are separately connected to the digital recorder; and
the digital recorder is configured to collect electrical quantities of a plurality of test points in the real-time digital simulator, and voltage and current of the sampling unit and a real-time waveform of a control signal of the switch quantity control unit in the to-be-tested hybrid energy storage controller, where the plurality of test points include an alternating current side outlet of the hybrid power conversion system, an alternating current side outlet of the conventional power conversion system, a bus side of the step-up transformer switch, one side of the grid-connected switch and a load side of the load switch.

According to a second aspect, embodiments of the present disclosure further provide a simulation test method for a hybrid power conversion system. The simulation test method for a hybrid power conversion system is applied to the simulation test system for a hybrid power conversion system, where the simulation test system for a hybrid power conversion system includes a simulation workstation, a real-time digital simulator, an I/O interface device, and a to-be-tested hybrid energy storage controller, and the simulation test method for a hybrid power conversion system includes:
the simulation workstation generating an operation control instruction in response to a user operation, and sending the operation control instruction to the real-time digital simulator;
the real-time digital simulator simulating an operation working condition or an abnormal working condition of various faults of the simulation workstation in real time, completing operation processing according to the operation control instruction, generating corresponding data volume, and sending the data volume to the I/O interface device through an optical fiber, where the data volume includes grid side voltage and current, direct current side voltage and current, a grid side switch state and a direct current side switch state;
the I/O interface device implementing data interaction between the real-time digital simulator and the to-be-tested hybrid energy storage controller, and sending the data volume generated by the real-time digital simulator to the to-be-tested hybrid energy storage controller;
the to-be-tested hybrid energy storage controller generating a switch tripping and closing instruction and a trigger pulse signal based on the received data volume, and sending the switch tripping and closing instruction and the trigger pulse signal to the real-time digital simulator through the I/O interface device, where the switch tripping and closing instruction includes a grid side switch tripping and closing instruction and a direct current side switch tripping and closing instruction; and
the real-time digital simulator sending the switch tripping and closing instruction and the trigger pulse signal to the simulation workstation, so that the simulation workstation performs simulation based on the switch tripping and closing instruction and the trigger pulse signal.

According to a third aspect, embodiments of the present disclosure further provide a performance detection method for a hybrid power conversion system based on dynamic simulation, where the performance detection method for a hybrid power conversion system is applied to a simulation test system for a hybrid power conversion system, and the performance detection method for a hybrid power conversion system includes:
a simulation workstation controlling a grid-connected switch and a step-up transformer switch in an energy storage substation and external power grid module to turn on and a switch corresponding to a conventional power conversion system in a hybrid power conversion system test model to turn on, so as to perform a grid-connected performance test of a megawatt-scale conventional power conversion system; and
the simulation workstation controlling the grid-connected switch and the step-up transformer switch in the energy storage substation and external power grid module to turn on and a switch corresponding to a hybrid power conversion system in the hybrid power conversion system test model to turn on, so as to perform a grid-connected performance test of a megawatt-scale hybrid power conversion system.

Further, the performance detection method for a hybrid power conversion system also includes:
the simulation workstation controlling the step-up transformer switch to turn on, a load switch in the energy storage substation and external power grid module to turn on, a switch corresponding to the conventional power conversion system to turn on and a switch corresponding to the hybrid power conversion system to turn on, and setting the conventional power conversion system to operate in a V/f operation mode and the to-be-tested hybrid power conversion system to operate in a P/Q operation mode, so as to form a multi-type power conversion system power self-loop mode, and to perform islanding protection function test on the hybrid power conversion system and the conventional power conversion system with multi-type adjustable loads; and
the simulation workstation controlling the grid-connected switch to turn on, the step-up transformer switch to turn on, a switch corresponding to the conventional power conversion system to turn on and a switch corresponding to the hybrid power conversion system to turn on, so as to perform interactive testing on the multi-type power conversion system grid connection.

According to a fourth aspect, embodiments of the present disclosure further provide an electronic device, including: a processor, a memory, and a bus, where the memory has machine-readable instructions stored thereon and executable by the processor, and when the electronic device is running, the processor communicates with the memory through the bus, and the steps of the simulation test method for a hybrid power conversion system and the performance detection method for a hybrid power conversion system based on dynamic simulation described above are performed when the machine-readable instructions are executed by the processor.

According to a fifth aspect, embodiments of the present disclosure further provide a computer-readable storage medium, where the computer-readable storage medium has a computer program stored thereon, and when the computer program is executed by a processor, the steps of the simulation test method for a hybrid power conversion system and the performance detection method for a hybrid power conversion system based on dynamic simulation described above are performed.

Embodiments of the present disclosure provide a simulation test system and a performance detection method for a hybrid power conversion system, where the simulation test system is formed by equipping an upper computer simulation workstation, a lower computer real-time digital simulator, an I/O interface device, a to-be-tested hybrid energy storage controller and a digital recorder, and a real-time digital simulation modeling basis is completed by using a modularized modeling thought. An energy storage power station, primary systems of a fossil-fuel power station and a new energy station are built in the simulation workstation, a hybrid power conversion system topology simulation model is provided, system modeling simulation can be performed on a megawatt-scale conventional power conversion system and a hybrid power conversion system, and detection of grid-connected performance of a SiC MOSFET and Si IGBT hybrid multi-level converter can be achieved. The grid-connected performance test of the megawatt-scale power conversion system, the islanding protection function test of the hybrid power conversion system and the conventional power conversion system with multi-type adjustable loads, and the interaction influence test among the power conversion systems can be performed by switching the switches, which has high integration and strong compatibility. The grid-connected performance detection requirements of various hybrid multi-level power conversion systems and controllers thereof in the market can be met.

To make the above objectives, features and advantages of the present disclosure comprehensible, preferred embodiments are illustrated below, and detail description is made with reference to the drawings below.

### BRIEF DESCRIPTION OF DRAWINGS

To more clearly illustrate the technical solutions of the embodiments of the present disclosure, the drawings required in the embodiments will be briefly described below. It should be understood that the following drawings only illustrate some embodiments of the present disclosure and therefore should not be considered as limitations of the scope, and for those of ordinary skill in the art, other related drawings can be obtained according to these drawings without paying creative efforts.

FIG. 1 is a schematic structural diagram of a simulation test system for a hybrid power conversion system according to embodiments of the present disclosure;

FIG. 2 is a schematic structural diagram of an energy storage substation and external power grid module according to embodiments of the present disclosure;

FIG. 3 is a schematic structural diagram of a hybrid power conversion system test model according to embodiments of the present disclosure;

FIG. 4 is a flowchart of a simulation test method for a hybrid power conversion system according to embodiments of the present disclosure; and

FIG. 5 is a schematic structural diagram of an electronic device according to embodiments of the present disclosure.

### DETAILED DESCRIPTION OF EMBODIMENTS

To make the objectives, technical solutions, and advantages of embodiments of the present disclosure clearer, the following clearly and completely describes the technical solutions in embodiments of the present disclosure with reference to the drawings in embodiments of the present disclosure. It is clear that the described embodiments are merely some rather than all of embodiments of the present disclosure. The components of the embodiments of the present disclosure, as generally described and illustrated in the drawings herein, can be arranged and designed in a wide variety of different configurations. Therefore, the following detailed description of the embodiments of the present disclosure provided in the drawings is not intended to limit the scope of the present disclosure as claimed, but is merely representative of selected embodiments of the present disclosure. Based on the embodiments of the present disclosure, each of other embodiments obtained by those skilled in the art without paying creative efforts falls within the protection scope of the present disclosure.

First, an application scenario to which the present disclosure is applicable will be described. The present disclosure may be applied to the technical field of simulation tests.

With the large-scale integration of new energy sources represented by wind energy and solar energy into a power grid and the application of a large number of power electronic devices in a power system, the power supply structure, power grid form, load characteristics, operation mode and the like will all undergo profound changes, which increases the difficulty of peak load and frequency regulation of the system. An energy storage power station is regarded as a power grid side technical solution to improve the frequency stability of the system, has unique advantages in peak cut and rapid frequency regulation, and can provide power response and inertia support for the power system.

A power conversion system (PCS) is a core component of an electric energy storage system. However, a topological structure and a control strategy of the power conversion system have a great impact on grid-connected performance, and a conventional solution based on a two-level converter is difficult to adapt to a high-proportion new energy power system containing large-scale energy storage. Therefore, high-capacity and hybrid type have become two major development trends and technical directions of energy storage system configuration.

It is found from the researches that in an aspect of high-capacity power conversion system topology, a distributed configuration solution based on a multi-level (three-level or more) converter is a preferable solution for achieving medium-voltage high-capacity alternating current-direct current electric energy conversion. Since it is difficult to further improve the performance of a silicon-based power device IGBT commonly used in recent years, a heterogeneous power device hybrid multi-level converter which is applied by mixing a silicon carbide MOSFET and a silicon device is beneficial to saving cost, reducing loss and improving power density and overall efficiency. However, related research is still in its infancy.

Meanwhile, the high-capacity hybrid energy storage technology lacks construction and operation experience at home, and especially lacks technical verification means. At present, for model verification of power electronic devices, relatively mature software such as PLECS and MATLAB/Simulink is mainly used for simulation modeling, which can analyze the electrical characteristics of components, converter topology, modulation strategies and the like from the device level. However, a simulation model and a dynamic simulation test platform for detecting a large-capacity power conversion system integrated with a hybrid energy storage unit are not available for reference, and there is a lack of an effective means and method for determining whether a control strategy is suitable for a large power grid after heterogeneous power device integration.

Based on this, embodiments of the present disclosure provide a simulation test system and a performance detection method for a hybrid power conversion system, which provide a semi-physical closed-loop simulation system and a detection method with strong adaptability and good compatibility for grid-connected performance of the hybrid power conversion system, and verify the electrical performance and the control strategy of the hybrid power conversion system, so that the simulation test system and the performance detection method are suitable for safe and stable operation of a large-scale energy storage power station.

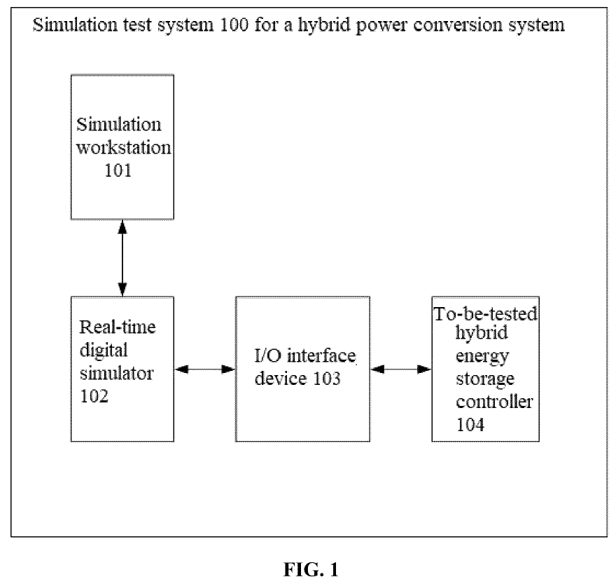

Referring to FIG. 1, FIG. 1 is a schematic structural diagram of a simulation test system for a hybrid power conversion system according to embodiments of the present disclosure. As shown in FIG. 1, the simulation test system 100 for a hybrid power conversion system includes a simulation workstation 101, a real-time digital simulator 102, an I/O interface device 103, and a to-be-tested hybrid energy storage controller 104, where the simulation workstation 101 is in communication with the real-time digital simulator 102, the real-time digital simulator 102 is connected to the I/O interface device 103 through an optical fiber, and the I/O interface device 103 is in communication with the to-be-tested hybrid energy storage controller 104.

The simulation workstation 101 is configured to generate an operation control instruction in response to a user operation and send the operation control instruction to the real-time digital simulator 102.

It should be noted that the operation control instruction refers to an instruction generated by the simulation workstation based on the user operation. For example, the operation control instruction may be an instruction to control a switch to turn on. This is not specifically limited in the present disclosure.

Here, the simulation workstation 101 is mainly responsible for performing model simulation, and the simulation workstation 101 generates an operation control instruction in response to a user operation and sends the generated operation control instruction to the real-time digital simulator 102. Specifically, the simulation workstation 101 is an upper computer, the simulation workstation 101 is a control host of the whole dynamic simulation system, carries a power system real-time simulation software and is configured to build an energy storage substation and external power grid module, a hybrid power conversion system model, an energy storage battery pack model and a fault simulation module, compiling codes are formed after model verification is passed and automatically loaded into a real-time simulator, and a simulation process can be accessed and controlled in real time through a human-computer interaction operation interface.

Specifically, the simulation workstation 101 includes an energy storage substation and external power grid module, a hybrid power conversion system test model, an energy storage battery pack model and a fault simulation module.

The energy storage substation and external power grid module is configured to simulate working states of the energy storage substation and an external equivalent power grid.

The hybrid power conversion system test model is configured to simulate the hybrid power conversion system.

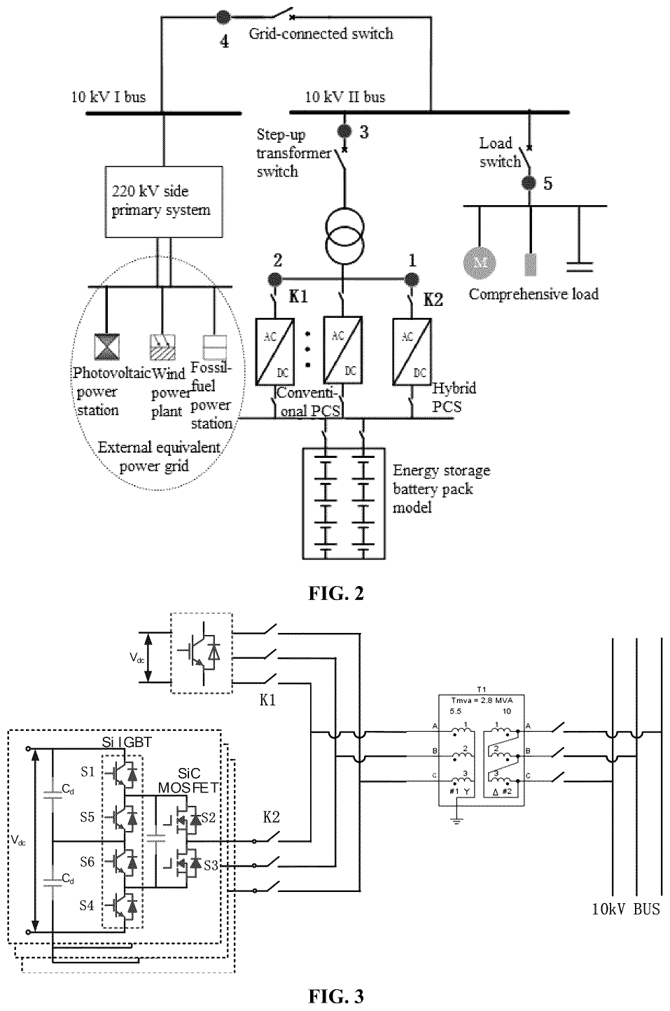

Referring to FIG. 2, FIG. 2 is a schematic structural diagram of an energy storage substation and external power grid module according to embodiments of the present disclosure. Referring to FIG. 2, the energy storage substation and external power grid module includes a 220 kV side primary system model of the energy storage substation, an external power grid model and a 10 kV energy storage side primary system model, where the 220 kV side primary system model further includes a 220 kV bus, a 110 kV bus, a 10 kV bus, a circuit breaker, a transformer and in-station reactive compensation equipment; the external power grid model further includes two 220 kV transmission lines, a wind power plant, a photovoltaic power station and a fossil-fuel power station; and the 10 kV energy storage side primary system model further includes a grid-connected switch, a step-up transformer switch, a load switch and a comprehensive load.

Further, the hybrid power conversion system test model includes at least one conventional power conversion system and a hybrid power conversion system model.

In the above, the hybrid power conversion system is simulated by using a hybrid three-level ANPC topology.

Here, the hybrid power conversion system test model includes at least one conventional power conversion system and a hybrid power conversion system model, and the hybrid energy storage controller is configured to connect a plurality of conventional power conversion systems to achieve synchronous operation of the plurality of conventional power conversion systems. Referring to FIG. 3, FIG. 3 is a schematic structural diagram of a hybrid power conversion system test model according to embodiments of the present disclosure. As shown in FIG. 3, FIG. 3 only shows an example that one conventional power conversion system is included in the hybrid power conversion system test model. In practice, a plurality of conventional power conversion systems may be included in the hybrid power conversion system test model. The simulation in the hybrid power conversion system provided in the embodiments of the present disclosure uses a hybrid three-level ANPC topology, where in each phase, S2 and S3 switches are SiC MOSFETs, S1, S4, S5 and S6 switches are Si IGBTs, and a proportion of the SiC is 1/3. With the modulation strategy of the controller, only SiC MOS high-frequency switches are arranged in the circuit, so that the conversion efficiency can be improved; and the Si IGBTs work on power frequency switches, for uniform low-frequency work, so that the switching loss is reduced and the cost is reduced. The switch K1 is connected to a conventional power conversion system, the switch K2 is connected to a hybrid power conversion system, and the Tl is a transformer.

The energy storage battery pack model is configured to form a battery cluster in a series-parallel connection mode and access the battery cluster to a direct current side in the energy storage substation and external power grid module.

Here, the energy storage battery pack model is mainly responsible for simulating an energy storage battery pack and providing a power source for the energy storage substation and external power grid module, and the energy storage battery pack model forms a battery cluster in a series-parallel connection mode and accesses the battery cluster to a direct current side in the energy storage substation and external power grid module. Specifically, the energy storage battery pack model is a lithium iron phosphate battery pack, a battery cluster is formed in a series-parallel connection mode and is connected to the direct current side of the power conversion system, and a state of charge (SOC) of the battery is solved by using a second-order RC equivalent circuit model and a state estimation method.

The fault simulation module is configured to simulate a fault state to verify a control protection function of a hybrid power conversion system in the hybrid power conversion system test model.

Here, the fault simulation module is mainly responsible for performing fault state simulation to verify a control protection function of a hybrid power conversion system in the hybrid power conversion system test model. Specifically, in a simulation software, the fault simulation module is configured with a plurality of short-circuit models and provided with fault points, trigger time and fault types, and is configured with a passive reactor to simulate grid voltage drop, so as to verify the control protection function of the hybrid power conversion system.

Therefore, according to the simulation test system for a hybrid power conversion system provided in the present disclosure, the hybrid power conversion system uses a hybrid three-level topology, where the SiC MOSFET switch and the Si IGBT switch are used respectively, and the grid-connected performance of the hybrid multi-level converter of the SiC MOSFET and the Si IGBT can be detected. The simulation test system further includes a fault simulation module, which can simulate various faults that may occur, so as to verify the control protection function of the hybrid power conversion system.

The real-time digital simulator 102 is configured to simulate an operation working condition or an abnormal working condition of various faults of the simulation workstation 101 in real time, complete operation processing according to the operation control instruction, generate corresponding data volume and send the data volume to the I/O interface device 103 through an optical fiber.

In the above, the data volume includes grid side voltage and current, direct current side voltage and current, grid side switch state and direct current side switch state. Specifically, the data volume includes grid side voltage and current of the hybrid power conversion system, direct current side voltage and current of the hybrid power conversion system, a grid side switch state of the hybrid power conversion system and a direct current side switch state of the hybrid power conversion system.

Here, the real-time digital simulator 102 is mainly configured to perform simulation according to an operation control instruction sent by an upper computer, perform processing according to a control operation instruction generated by the simulation workstation 101 to simulate an operation working condition or an abnormal working condition of various faults of the simulation workstation 101 in real time, complete operation processing according to the operation control instruction sent by the simulation workstation 101, generate corresponding grid side voltage and current, corresponding direct current side voltage and current, a corresponding grid side switch state, and a corresponding direct current side switch state, and send the data volume to the I/O interface device 103 through an optical fiber, so that the I/O interface device 103 sends the received data volume to the to-be-tested hybrid energy storage controller 104. Specifically, the real-time digital simulator 102 functions as a lower computer, and the real-time digital simulator 102 has a millisecond-level simulation step, is configured for electromagnetic transient simulation calculation, can simulate operation working conditions and an abnormal working conditions of various faults of the energy storage substation and the power conversion system in real time, has communication protocols such as 104 and 61850, completes operation processing according to the operation control instruction of the upper computer, generates corresponding analog quantity and digital quantity, and interacts with access equipment with an I/O module through an optical fiber.

The I/O interface device 103 is configured to implement data interaction between the real-time digital simulator 102 and the to-be-tested hybrid energy storage controller 104, and send the data volume generated by the real-time digital simulator 102 to the to-be-tested hybrid energy storage controller 104.

Here, the I/O interface device 103 is mainly configured to transmit data to the to-be-tested hybrid energy storage controller 104, so as to implement data interaction between the real-time digital simulator 102 and the to-be-tested hybrid energy storage controller 104 and send the data volume generated by the real-time digital simulator 102 to the to-be-tested hybrid energy storage controller 104. Specifically, the I/O interface device is configured to implement real-time interaction between a to-be-tested physical device and a simulator; and specifically includes an analog output board (analog quantity output board card) and a power amplifier that are configured to send voltages and currents of a grid-connected side and a direct current side of the hybrid power conversion system, and a digital output board (digital quantity output board card) that is configured to send switch states of the grid side and the direct current side of the hybrid power conversion system.

The to-be-tested hybrid energy storage controller 104 is configured to generate a switch tripping and closing instruction and a trigger pulse signal based on the received data volume, and send the switch tripping and closing instruction and the trigger pulse signal to the real-time digital simulator 102 through the I/O interface device 103.

Here, the to-be-tested hybrid energy storage controller 104 is mainly configured to generate instructions and signals according to the received data volume, and return the generated instructions and signals to the real-time digital simulator 102 through the I/O interface device 103, so that the real-time digital simulator 102 returns the instructions and signals generated by the to-be-tested hybrid energy storage controller 104 to the simulation workstation 101. The to-be-tested hybrid energy storage controller 104 generates a switch tripping and closing instruction and a trigger pulse signal based on the received data volume, and sends the generated switch tripping and closing instruction and trigger pulse signal to the real-time digital simulator 102 through the I/O interface device 103. In the above, the switch tripping and closing instruction includes a grid side switch tripping and closing instruction and a direct current side switch tripping and closing instruction. Specifically, the switch tripping and closing instruction includes a grid side switch tripping and closing instruction of the hybrid power conversion system and a direct current side switch tripping and closing instruction of the hybrid power conversion system.

Here, the I/O interface device 103 further includes a digital input board (digital quantity input board card) that is configured to receive a grid side switch tripping and closing instruction and a direct current side switch tripping and closing instruction of the hybrid power conversion system and a trigger pulse signal sent by the to-be-tested hybrid energy storage controller 104.

Further, the to-be-tested hybrid energy storage controller includes a sampling unit, a switch quantity control unit and a drive circuit.

The sampling unit is configured to collect the grid side voltage and current and the direct current side voltage and current which are sent by the I/O interface device.

The switch quantity control unit is configured to generate the grid side switch tripping and closing instruction and the direct current side switch tripping and closing instruction based on the grid side switch state and the direct current side switch state.

The drive circuit is configured to generate the trigger pulse signal.

Specifically, the to-be-tested hybrid energy storage controller 104 is configured to receive the grid side and direct current side electrical quantities. The switch states and the tripping and closing instructions of the grid side and direct current side are used as interaction signals of the switch quantity control unit, a modulation algorithm is implemented by a control board, and the trigger pulse signal is output from the IGBT and MOSFET drive circuits, so that the strategy execution of the to-be-tested hybrid energy storage controller is completed.

Here, according to the embodiments provided by the present disclosure, an SVM modulation method is used as the modulation strategy of the to-be-tested hybrid energy storage controller 104. Referring to Table 1, Table 1 shows a switch state setting relationship table provided by embodiments of the present disclosure. For the four switch states as shown in Table 1 below, when the output level is switched between −1 and 0, an N switch state and a U switch state are used, and when the output level is switched between 1 and 0, a P switch state and an L switch state are used. This selection can ensure that the S1, the S4, the S5 and the S6 do not perform switching (switch motion) basically, and one switching only occurs when a polarity of an output voltage is changed, namely, the Si IGBT devices work under the power frequency condition, so that the effect of switching the power frequency of the Si IGBT devices is achieved, the switching loss is totally concentrated on the SiC devices, and the maximization of the overall efficiency of the hybrid energy storage controller is achieved.

TABLE 1
Switch state setting relationship table

| Switch state | Output level | Sₓ₁ | Sₓ₂ | Sₓ₃ | Sₓ₄ | Sₓ₅ | Sₓ₆ |
|---|---|---|---|---|---|---|---|
| N | −1 | 0 | 0 | 1 | 1 | 1 | 0 |
| U | 0 | 0 | 1 | 0 | 1 | 1 | 0 |
| L | | 1 | 0 | 1 | 0 | 0 | 1 |
| P | 1 | 1 | 1 | 0 | 0 | 0 | 1 |

The real-time digital simulator 102 is configured to send the switch tripping and closing instruction and the trigger pulse signal to the simulation workstation 101, so that the simulation workstation 101 performs simulation based on the switch tripping and closing instruction and the trigger pulse signal.

Here, the real-time digital simulator 102 sends the switch tripping and closing instruction and the trigger pulse signal to the simulation workstation 101 after receiving the switch tripping and closing instruction and the trigger pulse signal sent by the to-be-tested hybrid energy storage controller 104, so that the simulation workstation 101 performs simulation based on the switch tripping and closing instruction and the trigger pulse signal.

In an optional embodiment, the simulation test system 100 for a hybrid power conversion system provided by the present disclosure further includes a digital recorder, and the real-time digital simulator 102 and the to-be-tested hybrid energy storage controller 104 are separately connected to the digital recorder.

The digital recorder is configured to collect electrical quantities of a plurality of test points in the real-time digital simulator 102, and voltage and current of the sampling unit and a real-time waveform of a control signal of the switch quantity control unit in the to-be-tested hybrid energy storage controller 104.

In the above, the plurality of test points include an alternating current side outlet of the hybrid power conversion system, an alternating current side outlet of the conventional power conversion system, a bus side of the step-up transformer switch, one side of the grid-connected switch and a load side of the load switch.

Specifically, the digital recorder is mainly configured to record the electrical quantities of 5 test points, and voltage and current of the sampling unit and a real-time waveform of a control signal of the switch quantity control unit in the to-be-tested hybrid energy storage controller. Positions of the test points are as shown in FIG. 2, the test point 1 is arranged at an alternating current side outlet of the hybrid power conversion system, the test point 2 is arranged at an alternating current side outlet of the conventional power conversion system, the test point 3 is arranged at a bus side of the step-up transformer switch, the test point 4 is arranged at a 10 kV I bus side of the grid-connected switch, and the test point 5 is arranged at a load side of the load switch.

According to the simulation test system for a hybrid power conversion system provided in the embodiments of the present disclosure, the simulation test system is formed by equipping an upper computer simulation workstation, a lower computer real-time digital simulator, an I/O interface device, a to-be-tested hybrid energy storage controller and a digital recorder, and a real-time digital simulation modeling basis is completed by using a modularized modeling thought. An energy storage power station, and primary systems of a fossil-fuel power station and a new energy station are built in the simulation workstation, a hybrid power conversion system topology simulation model is provided, which can perform system modeling simulation on a megawatt-scale conventional power conversion system and a hybrid power conversion system, and achieve detection of grid-connected performance of a SiC MOSFET and Si IGBT hybrid multi-level converter.

The present disclosure further provides a performance detection method for a hybrid power conversion system based on dynamic simulation, which is applied to the simulation test system for a hybrid power conversion system provided in the embodiments of the present disclosure, and the performance detection method for a hybrid power conversion system includes:
a simulation workstation controlling a grid-connected switch and a step-up transformer switch in an energy storage substation and external power grid module to turn on, and a switch corresponding to a conventional power conversion system in a hybrid power conversion system test model to turn on, so as to perform a grid-connected performance test of a megawatt-scale conventional power conversion system.

Here, the grid-connected switch in an energy storage substation and external power grid module is turned on, the step-up transformer switch in an energy storage substation and external power grid module is turned on, and the switch K1 corresponding to a conventional power conversion system in a hybrid power conversion system test model is turned on, so that a grid-connected performance test of a megawatt-scale conventional power conversion system is performed.

The simulation workstation controls the grid-connected switch and the step-up transformer switch in the energy storage substation and external power grid module to turn on, and a switch corresponding to a hybrid power conversion system in the hybrid power conversion system test model to turn on, so as to perform a grid-connected performance test of a megawatt-scale hybrid power conversion system.

Here, the grid-connected switch and the step-up transformer switch in the energy storage substation and external power grid module are turned on, and a switch K2 corresponding to a hybrid power conversion system in a hybrid power conversion system test model is turned on, so that a grid-connected performance test of a megawatt-scale hybrid power conversion system is performed.

Through the above two modes, the voltage and frequency adaptability test, the dynamic power test, the high-low voltage ride-through test and the protection function test of a high-capacity conventional power conversion system and a hybrid power conversion system can be conducted.

Further, the performance detection method for a hybrid power conversion system provided by the present disclosure further includes:
the simulation workstation controlling the step-up transformer switch to turn on, a load switch in the energy storage substation and external power grid module to turn on, a switch corresponding to the conventional power conversion system to turn on and a switch corresponding to the hybrid power conversion system to turn on, and setting the conventional power conversion system to operate in a V/f operation mode and the to-be-tested hybrid power conversion system to operate in a P/Q operation mode, so as to form a multi-type power conversion system power self-loop mode, and to perform islanding protection function test on the hybrid power conversion system and the conventional power conversion system with multi-type adjustable loads.

Here, the step-up transformer switch is turned on, the load switch in the energy storage substation and external power grid module is turned on, the switch K1 corresponding to the conventional power conversion system is turned on, the switch K2 corresponding to the hybrid power conversion system is turned on, the conventional power conversion system is set to operate in a V/f operation mode, and the to-be-tested hybrid power conversion system is set to operate in a P/Q operation mode to form a multi-type power conversion system power self-loop mode, so that an islanding protection function test of the hybrid power conversion system and the conventional power conversion system with multi-type adjustable loads can be performed.

The simulation workstation controls the grid-connected switch to turn on, the step-up transformer switch to turn on, a switch corresponding to the conventional power conversion system to turn on and a switch corresponding to the hybrid power conversion system to turn on, so as to perform interactive testing on the multi-type power conversion system grid connection.

Here, the grid-connected switch, the step-up transformer switch, the switch corresponding to the conventional power conversion system and the switch K2 corresponding to the hybrid power conversion system are turned on, so that an interactive test of the multi-type power conversion system grid connection can be achieved, and the circulation test and balance control strategy research of power electronic equipment can be developed.

According to the performance detection method for a hybrid power conversion system provided in the embodiments of the present disclosure, the grid-connected performance test of the megawatt-scale power conversion system, the islanding protection function test of the hybrid power conversion system and the conventional power conversion system with multi-type adjustable loads, and the interaction influence test among the power conversion systems can be performed by switching the switches, which has high integration and strong compatibility. The grid-connected performance detection requirements of various hybrid multi-level power conversion systems and controllers thereof in the market can be met.

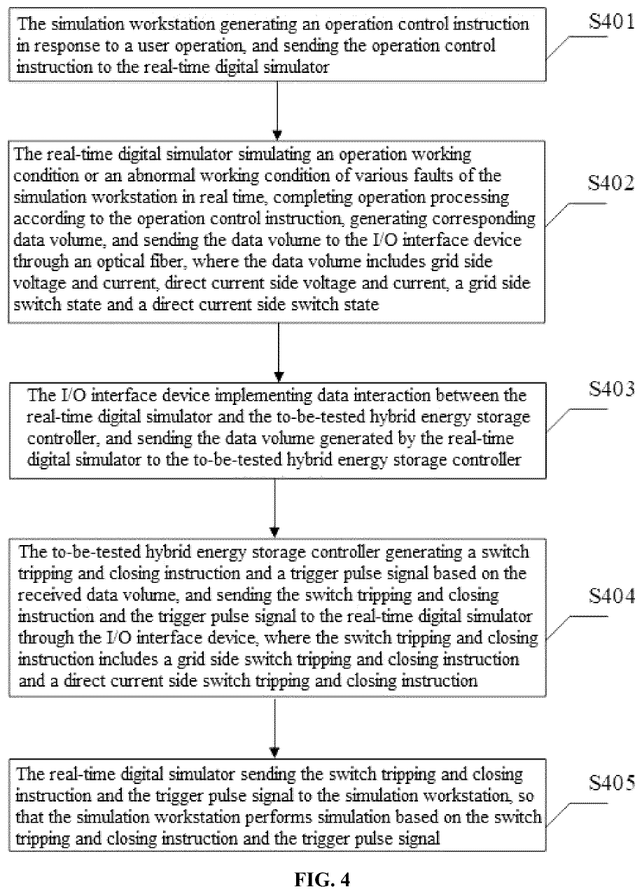

Referring to FIG. 4, FIG. 4 is a flowchart of a simulation test method for a hybrid power conversion system according to embodiments of the present disclosure. As shown in FIG. 4, the simulation test method for a hybrid power conversion system provided in the embodiments of the present disclosure is applied to the simulation test system for a hybrid power conversion system provided in the embodiments of the present disclosure, where the simulation test system for a hybrid power conversion system includes a simulation workstation, a real-time digital simulator, an I/O interface device, and a to-be-tested hybrid energy storage controller, and the simulation test method for a hybrid power conversion system includes:
S401: the simulation workstation generating an operation control instruction in response to a user operation, and sending the operation control instruction to the real-time digital simulator;
S402: the real-time digital simulator simulating an operation working condition or an abnormal working condition of various faults of the simulation workstation in real time, completing operation processing according to the operation control instruction, generating corresponding data volume, and sending the data volume to the I/O interface device through an optical fiber; where the data volume includes grid side voltage and current, direct current side voltage and current, a grid side switch state and a direct current side switch state;
S403: the I/O interface device implementing data interaction between the real-time digital simulator and the to-be-tested hybrid energy storage controller, and sending the data volume generated by the real-time digital simulator to the to-be-tested hybrid energy storage controller;
S404: the to-be-tested hybrid energy storage controller generating a switch tripping and closing instruction and a trigger pulse signal based on the received data volume, and sending the switch tripping and closing instruction and the trigger pulse signal to the real-time digital simulator through the I/O interface device, where the switch tripping and closing instruction includes a grid side switch tripping and closing instruction and a direct current side switch tripping and closing instruction; and
S405: the real-time digital simulator sending the switch tripping and closing instruction and the trigger pulse signal to the simulation workstation, so that the simulation workstation performs simulation based on the switch tripping and closing instruction and the trigger pulse signal.

Further, the simulation workstation includes an energy storage substation and external power grid module, a hybrid power conversion system test model, an energy storage battery pack model and a fault simulation module; and the simulation test method for a hybrid power conversion system further includes:
the energy storage substation and external power grid module simulating working states of the energy storage substation and an external equivalent power grid;
the hybrid power conversion system test model simulating the hybrid power conversion system;
the energy storage battery pack model forming a battery cluster in a series-parallel connection mode and accessing the battery cluster to a direct current side in the energy storage substation and external power grid module; and the fault simulation module simulating a fault state to verify a control protection function of a hybrid power conversion system in the hybrid power conversion system test model.

Further, the energy storage substation and external power grid module includes a 220 kV side primary system model of the energy storage substation, an external power grid model and a 10 kV energy storage side primary system model;
the 220 kV side primary system model further includes a 220 k V bus, a 110 kV bus, a 10 kV bus, a circuit breaker, a transformer and in-station reactive compensation equipment;
the external power grid model further includes two 220 kV transmission lines, a wind power plant, a photovoltaic power station and a fossil-fuel power station;
the 10 kV energy storage side primary system model further includes a grid-connected switch, a step-up transformer switch, a load switch and a comprehensive load; and
the hybrid power conversion system test model includes at least one conventional power conversion system and a hybrid power conversion system model, where the hybrid power conversion system is simulated by using a hybrid three-level ANPC topology.

Further, the to-be-tested hybrid energy storage controller includes a sampling unit, a switch quantity control unit and a drive circuit, and the simulation test method for a hybrid power conversion system further includes:
the sampling unit collecting the grid side voltage and current and the direct current side voltage and current sent by the I/O interface device;
the switch quantity control unit generating the grid side switch tripping and closing instruction and the direct current side switch tripping and closing instruction based on the grid side switch state and the direct current side switch state; and
the drive circuit generating the trigger pulse signal.

Further, the simulation test system for a hybrid power conversion system further includes a digital recorder, where the real-time digital simulator and the to-be-tested hybrid energy storage controller are separately connected to the digital recorder, and the simulation test method for a hybrid power conversion system further includes:
the digital recorder collecting electrical quantities of a plurality of test points in the real-time digital simulator, and voltage and current of the sampling unit and a real-time waveform of a control signal of the switch quantity control unit in the to-be-tested hybrid energy storage controller, where the plurality of test points include an alternating current side outlet of the hybrid power conversion system, an alternating current side outlet of the conventional power conversion system, a bus side of the step-up transformer switch, one side of the grid-connected switch and a load side of the load switch.

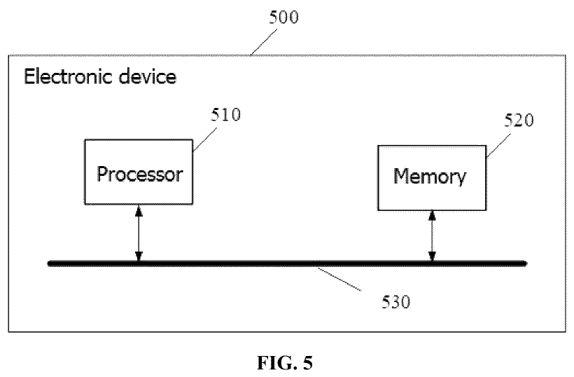

Referring to FIG. 5, FIG. 5 is a schematic structural diagram of an electronic device according to embodiments of the present disclosure. As shown in FIG. 5, the electronic device 500 includes a processor 510, a memory 520, and a bus 530.

The memory 520 stores machine-readable instructions executable by the processor 510, and when the electronic device 500 is running, the processor 510 communicates with the memory 520 through the bus 530, and the steps of the performance detection method for a hybrid power conversion system described in the method embodiments above may be performed when the machine-readable instructions are executed by the processor 510. For a specific implementation, referring to the method embodiment. Details are not described herein again.

Embodiments of the present disclosure further provide a computer-readable storage medium, where the computer-readable storage medium stores a computer program, and when the computer program is executed by a processor, the steps of the performance detection method for a hybrid power conversion system described in the method embodiments above may be performed. For a specific implementation, referring to the method embodiment. Details are not described herein again.

It may be clearly understood by those skilled in the art that, for the purpose of convenient and brief description, for a detailed working process of the foregoing system, apparatus, and unit, reference may be made to a corresponding process in the foregoing method embodiments, and details are not described here again.

In the several embodiments provided in the present disclosure, it should be understood that the disclosed system, apparatus and method may be implemented in other manners. The apparatus embodiment described above is merely illustrative. For example, the division of the units is only a division based on logical function, and it can be implemented in other ways in an actual situation. For another example, a plurality of units or components may be combined or integrated into another system, or some features may be omitted or not implemented. In addition, the shown or discussed coupling, direct coupling or communication therebetween may be realized through some communicative interfaces, and indirect coupling or communication between apparatuses or units may be in electrical, mechanical or other forms.

The units described as separate parts may or may not be physically separate, and parts displayed as units may or may not be physical units, may be located in one position, or may be distributed on a plurality of network units. Some or all of the units may be selected based on actual requirements to achieve the objectives of the solutions of embodiments.

In addition, functional units in embodiments of the present disclosure may be integrated into one processing unit, each of the units may exist alone physically, or two or more units may be integrated into one unit.

The function, if implemented in a form of a software functional unit and sold or used as an independent product, may be stored in a non-transitory computer-readable storage medium executable by a processor. Based on such understanding, the technical solutions of the present disclosure essentially can be, or part of the technical solutions contributing to the prior art can be, or part of the technical solutions can be embodied in the form of a software product. The computer software product is stored in a storage medium and includes several instructions for enabling a computer device (which may be a personal computer, a server, a network device or the like) to implement all or part of the steps of the method described in the embodiments of the present disclosure. The foregoing storage medium includes various medium that can store program code, such as a USB flash drive, a removable hard disk, a read-only memory (ROM), a random access memory (RAM), a magnetic disk, or an optical disc.

Finally, it should be noted that the foregoing embodiments are only specific implementations of the present disclosure, and are used to illustrate the technical solutions of the present disclosure, but not for limiting the present disclosure, and the protection scope of the present disclosure is not limited thereto. Although the present disclosure is described in detail with reference to the foregoing embodiments, those of ordinary skill in the art should understand that: those skilled in the art may still modify or easily think of changes to the technical solutions described in the foregoing embodiments within the technical scope disclosed in the present disclosure, or make equivalent replacements to some technical features thereof. These modifications, changes, or substitutions do not make the essence of the corresponding technical solutions depart from the spirit and scope of the technical solutions of the embodiments of the present disclosure, and shall fall within the protection scope of the present disclosure. Therefore, the protection scope of the present disclosure shall be subject to the protection scope of the claims.

### INDUSTRIAL APPLICABILITY

The present disclosure provides a simulation test system and a performance detection method for a hybrid power conversion system. The system includes a simulation workstation, a real-time digital simulator, an I/O interface device, and a to-be-tested hybrid energy storage controller, where the simulation workstation sends an operation control instruction to the real-time digital simulator; the real-time digital simulator simulates an operation working condition or an abnormal working condition of various faults of the simulation workstation in real time; the I/O interface device implements data interaction between the real-time digital simulator and the to-be-tested hybrid energy storage controller; the to-be-tested hybrid energy storage controller generates a switch tripping and closing instruction and a trigger pulse signal; and the real-time digital simulator sends the switch tripping and closing instruction and the trigger pulse signal to the simulation workstation, so that the simulation workstation performs simulation based on the switch tripping and closing instruction and the trigger pulse signal. Therefore, a semi-physical closed-loop simulation system and a detection method with strong adaptability and good compatibility are provided for the grid-connected performance of the hybrid power conversion system.

In addition, it should be understood that the simulation test system and the performance detection method for a hybrid power conversion system are reproducible and may be applied to a variety of industrial applications. For example, the simulation test system and the performance detection method for a hybrid power conversion system according to the present disclosure may be used in the technical field of simulation tests.

What is claimed is:

1. A simulation test system for a hybrid power conversion system, comprising: a simulation workstation, a real-time digital simulator, an I/O interface device, and a to-be-tested hybrid energy storage controller, wherein the simulation workstation is in communication with the real-time digital simulator, the real-time digital simulator is connected to the I/O interface device through an optical fiber, and the I/O interface device is in communication with the to-be-tested hybrid energy storage controller;
the simulation workstation is configured to generate an operation control instruction in response to a user operation, and send the operation control instruction to the real-time digital simulator;
the real-time digital simulator is configured to simulate an operation working condition or an abnormal working condition of various faults of the simulation workstation in real time, complete operation processing according to the operation control instruction, generate corresponding data volume and send the data volume to the I/O interface device through the optical fiber, wherein the data volume comprises grid side voltage and current, direct current side voltage and current, a grid side switch state and a direct current side switch state;
the I/O interface device is configured to implement data interaction between the real-time digital simulator and the to-be-tested hybrid energy storage controller and send the data volume generated by the real-time digital simulator to the to-be-tested hybrid energy storage controller;
the to-be-tested hybrid energy storage controller is configured to generate a switch tripping and closing instruction and a trigger pulse signal based on the received data volume and send the switch tripping and closing instruction and the trigger pulse signal to the real-time digital simulator through the I/O interface device, wherein the switch tripping and closing instruction comprises a grid side switch tripping and closing instruction and a direct current side switch tripping and closing instruction; and
the real-time digital simulator is configured to send the switch tripping and closing instruction and the trigger pulse signal to the simulation workstation, so that the simulation workstation performs simulation based on the switch tripping and closing instruction and the trigger pulse signal.

2. The simulation test system according to claim 1, wherein the simulation workstation comprises an energy storage substation and external power grid module, a hybrid power conversion system test model, an energy storage battery pack model and a fault simulation module;
the energy storage substation and external power grid module is configured to simulate working states of an energy storage substation and an external equivalent power grid;
the hybrid power conversion system test model is configured to simulate the hybrid power conversion system;
the energy storage battery pack model is configured to form a battery cluster in a series-parallel connection mode and access the battery cluster to a direct current side in the energy storage substation and external power grid module; and
the fault simulation module is configured to simulate a fault state to verify a control protection function of the hybrid power conversion system in the hybrid power conversion system test model.

3. The simulation test system according to claim 2, wherein the energy storage substation and external power grid module comprises a 220 kV side primary system model of the energy storage substation, an external power grid model and a 10 kV energy storage side primary system model;
the 220 kV side primary system model further comprises a 220 kV bus, a 110 kV bus, a 10 kV bus, a circuit breaker, a transformer and in-station reactive compensation equipment;
the external power grid model further comprises two 220 kV transmission lines, a wind power plant, a photovoltaic power station and a fossil-fuel power station;
the 10 kV energy storage side primary system model further comprises a grid-connected switch, a step-up transformer switch, a load switch and a comprehensive load; and
the hybrid power conversion system test model comprises at least one conventional power conversion system and a hybrid power conversion system model, wherein the hybrid power conversion system is simulated by using a hybrid three-level ANPC topology.

4. The simulation test system according to claim 3, wherein the to-be-tested hybrid energy storage controller comprises a sampling unit, a switch quantity control unit and a drive circuit;
the sampling unit is configured to collect the grid side voltage and current and the direct current side voltage and current sent by the I/O interface device;
the switch quantity control unit is configured to generate the grid side switch tripping and closing instruction and the direct current side switch tripping and closing instruction based on the grid side switch state and the direct current side switch state; and
the drive circuit is configured to generate the trigger pulse signal.

5. The simulation test system according to claim 4, further comprising a digital recorder, and the real-time digital simulator and the to-be-tested hybrid energy storage controller are connected to the digital recorder respectively,
wherein the digital recorder is configured to collect electrical quantities of a plurality of test points in the real-time digital simulator, and voltage and current of the sampling unit and a real-time waveform of a control signal of the switch quantity control unit in the to-be-tested hybrid energy storage controller, wherein the plurality of test points comprise an alternating current side outlet of the hybrid power conversion system, an alternating current side outlet of the at least one conventional power conversion system, a bus side of the step-up transformer switch, one side of the grid-connected switch and a load side of the load switch.

6. A simulation test method for a hybrid power conversion system, applicable to the simulation test system according to claim 1, wherein the simulation test system comprises a simulation workstation, a real-time digital simulator, an I/O interface device, and a to-be-tested hybrid energy storage controller, and the simulation test method comprises:
the simulation workstation generating an operation control instruction in response to a user operation, and sending the operation control instruction to the real-time digital simulator;
the real-time digital simulator simulating an operation working condition or an abnormal working condition of various faults of the simulation workstation in real time, completing operation processing according to the operation control instruction, generating corresponding data volume, and sending the data volume to the I/O interface device through an optical fiber, wherein the data volume comprises grid side voltage and current, direct current side voltage and current, a grid side switch state and a direct current side switch state;
the I/O interface device implementing data interaction between the real-time digital simulator and the to-be-tested hybrid energy storage controller, and sending the data volume generated by the real-time digital simulator to the to-be-tested hybrid energy storage controller;
the to-be-tested hybrid energy storage controller generating a switch tripping and closing instruction and a trigger pulse signal based on the received data volume, and sending the switch tripping and closing instruction and the trigger pulse signal to the real-time digital simulator through the I/O interface device, wherein the switch tripping and closing instruction comprises a grid side switch tripping and closing instruction and a direct current side switch tripping and closing instruction; and
the real-time digital simulator sending the switch tripping and closing instruction and the trigger pulse signal to the simulation workstation, so that the simulation workstation performs simulation based on the switch tripping and closing instruction and the trigger pulse signal.

7. A performance detection method for a hybrid power conversion system based on dynamic simulation, applicable to the simulation test system according to claim 1, wherein the performance detection method comprises:
the simulation workstation controlling a grid-connected switch and a step-up transformer switch in an energy storage substation and external power grid module to turn on and a switch corresponding to a conventional power conversion system in a hybrid power conversion system test model to turn on, so as to perform a grid-connected performance test of a megawatt-scale conventional power conversion system; and
the simulation workstation controlling the grid-connected switch and the step-up transformer switch in the energy storage substation and external power grid module to turn on and a switch corresponding to a hybrid power conversion system in the hybrid power conversion system test model to turn on, so as to perform a grid-connected performance test of a megawatt-scale hybrid power conversion system.

8. The performance detection method according to claim 7, further comprising:
the simulation workstation controlling the step-up transformer switch to turn on, a load switch in the energy storage substation and external power grid module to turn on, the switch corresponding to the conventional power conversion system to turn on and the switch corresponding to the hybrid power conversion system to turn on, and setting the conventional power conversion system to operate in a V/f operation mode and the to-be-tested hybrid power conversion system to operate in a P/Q operation mode, so as to form a multi-type power conversion system power self-loop mode, and to perform islanding protection function test on the hybrid power conversion system and the conventional power conversion system with multi-type adjustable loads; and
the simulation workstation controlling the grid-connected switch to turn on, the step-up transformer switch to turn on, the switch corresponding to the conventional power conversion system to turn on and the switch corresponding to the hybrid power conversion system to turn on, so as to perform interactive testing on multi-type power conversion system grid connection.

9. (canceled)

10. (canceled)

11. The simulation test method according to claim 6, wherein the simulation workstation comprises an energy storage substation and external power grid module, a hybrid power conversion system test model, an energy storage battery pack model and a fault simulation module;
the energy storage substation and external power grid module is configured to simulate working states of an energy storage substation and an external equivalent power grid;
the hybrid power conversion system test model is configured to simulate the hybrid power conversion system;
the energy storage battery pack model is configured to form a battery cluster in a series-parallel connection mode and access the battery cluster to a direct current side in the energy storage substation and external power grid module; and
the fault simulation module is configured to simulate a fault state to verify a control protection function of the hybrid power conversion system in the hybrid power conversion system test model.

12. The simulation test method according to claim 11, wherein the energy storage substation and external power grid module comprises a 220 kV side primary system model of the energy storage substation, an external power grid model and a 10 kV energy storage side primary system model;
the 220 kV side primary system model further comprises a 220 kV bus, a 110 kV bus, a 10 kV bus, a circuit breaker, a transformer and in-station reactive compensation equipment;
the external power grid model further comprises two 220 kV transmission lines, a wind power plant, a photovoltaic power station and a fossil-fuel power station;
the 10 kV energy storage side primary system model further comprises a grid-connected switch, a step-up transformer switch, a load switch and a comprehensive load; and
the hybrid power conversion system test model comprises at least one conventional power conversion system and a hybrid power conversion system model, wherein the hybrid power conversion system is simulated by using a hybrid three-level ANPC topology.

13. The simulation test method according to claim 12, wherein the to-be-tested hybrid energy storage controller comprises a sampling unit, a switch quantity control unit and a drive circuit;
the sampling unit is configured to collect the grid side voltage and current and the direct current side voltage and current sent by the I/O interface device;
the switch quantity control unit is configured to generate the grid side switch tripping and closing instruction and the direct current side switch tripping and closing instruction based on the grid side switch state and the direct current side switch state; and
the drive circuit is configured to generate the trigger pulse signal.

14. The simulation test method according to claim 13, wherein the simulation test system further comprises a digital recorder, and the real-time digital simulator and the to-be-tested hybrid energy storage controller are connected to the digital recorder respectively; and
the digital recorder is configured to collect electrical quantities of a plurality of test points in the real-time digital simulator, and voltage and current of the sampling unit and a real-time waveform of a control signal of the switch quantity control unit in the to-be-tested hybrid energy storage controller, wherein the plurality of test points comprise an alternating current side outlet of the hybrid power conversion system, an alternating current side outlet of the at least one conventional power conversion system, a bus side of the step-up transformer switch, one side of the grid-connected switch and a load side of the load switch.

15. The performance detection method according to claim 7, wherein the simulation workstation comprises an energy storage substation and external power grid module, a hybrid power conversion system test model, an energy storage battery pack model and a fault simulation module;
the energy storage substation and external power grid module is configured to simulate working states of an energy storage substation and an external equivalent power grid;
the hybrid power conversion system test model is configured to simulate the hybrid power conversion system;
the energy storage battery pack model is configured to form a battery cluster in a series-parallel connection mode and access the battery cluster to a direct current side in the energy storage substation and external power grid module; and
the fault simulation module is configured to simulate a fault state to verify a control protection function of the hybrid power conversion system in the hybrid power conversion system test model.

16. The performance detection method according to claim 15, wherein the energy storage substation and external power grid module comprises a 220 kV side primary system model of the energy storage substation, an external power grid model and a 10 kV energy storage side primary system model;
the 220 kV side primary system model further comprises a 220 kV bus, a 110 kV bus, a 10 kV bus, a circuit breaker, a transformer and in-station reactive compensation equipment;
the external power grid model further comprises two 220 kV transmission lines, a wind power plant, a photovoltaic power station and a fossil-fuel power station;
the 10 kV energy storage side primary system model further comprises a grid-connected switch, a step-up transformer switch, a load switch and a comprehensive load; and
the hybrid power conversion system test model comprises at least one conventional power conversion system and a hybrid power conversion system model, wherein the hybrid power conversion system is simulated by using a hybrid three-level ANPC topology.

17. The performance detection method according to claim 16, wherein the to-be-tested hybrid energy storage controller comprises a sampling unit, a switch quantity control unit and a drive circuit;
the sampling unit is configured to collect the grid side voltage and current and the direct current side voltage and current sent by the I/O interface device;
the switch quantity control unit is configured to generate the grid side switch tripping and closing instruction and the direct current side switch tripping and closing instruction based on the grid side switch state and the direct current side switch state; and
the drive circuit is configured to generate the trigger pulse signal.

18. The performance detection method according to claim 17, wherein the simulation test system further comprises a digital recorder, and the real-time digital simulator and the to-be-tested hybrid energy storage controller are connected to the digital recorder respectively; and
the digital recorder is configured to collect electrical quantities of a plurality of test points in the real-time digital simulator, and voltage and current of the sampling unit and a real-time waveform of a control signal of the switch quantity control unit in the to-be-tested hybrid energy storage controller, wherein the plurality of test points comprise an alternating current side outlet of the hybrid power conversion system, an alternating current side outlet of the at least one conventional power conversion system, a bus side of the step-up transformer switch, one side of the grid-connected switch and a load side of the load switch.
